(19) United States
(12) Patent Application Publication
(10) Pub. No.: US 2025/0357283 A1
(43) Pub. Date: Nov. 20, 2025

(54) SEMICONDUCTOR DEVICE

(71) Applicant: Rohm Co., Ltd., Kyoto-shi (JP)

(72) Inventors: Katsutoki SHIRAI, Kyoto-shi (JP); Shunya MIKAMI, Kyoto-shi (JP); Yosui FUTAMURA, Kyoto-shi (JP)

(21) Appl. No.: 19/288,125

(22) Filed: Aug. 1, 2025

Related U.S. Application Data
(63) Continuation of application No. PCT/JP2024/003633, filed on Feb. 5, 2024.

(30) Foreign Application Priority Data
Feb. 8, 2023 (JP) 2023-017617

(51) Int. Cl. H01L 23/495; H01L 23/00; H01L 23/31

(52) U.S. Cl. CPC H01L 23/49555; H01L 23/3114; H01L 23/49513; H01L 24/32; H01L 24/48; H01L 24/73; H01L 2224/32245; H01L 2224/48175; H01L 2224/73265; H01L 2924/3512

(57) ABSTRACT

The semiconductor device includes a first lead on which the semiconductor element is mounted, a plurality of second leads, and a sealing resin. The sealing resin includes first resin side surfaces located on the respective sides in a first direction, and second resin side surfaces located on the respective sides in a second direction. The first lead has a first end surface exposed from one of the first resin side surfaces. The second leads protrude from the second resin side surfaces in the second direction. The first end surface includes a first edge located on a first side in the thickness direction. Each of the second leads includes a second edge located on the first side in the thickness direction, in an area where the second lead intersects one of the second resin side surfaces. The first edge is located on a second side in the thickness direction relative to the second edge.

### TECHNICAL FIELD

The present disclosure relates to a semiconductor device.

### BACKGROUND ART

Various configurations have been proposed for a semiconductor device including a semiconductor element. JP-A-2022-143166 discloses an example of a conventional semiconductor device. The semiconductor device disclosed in this document includes a semiconductor element, a first lead on which the semiconductor element is mounted, a plurality of second leads, and a sealing resin. The first lead includes a die pad on which the semiconductor element is mounted, and fixing portions (34, 35) connected to the die pad. Each of the fixing portions (34, 35) includes an inclined portion (343, 353) that bends in a z direction, which is a thickness direction, and a parallel portion (342, 352) connected to the inclined portion. The parallel portions (342, 352) have end surfaces (341, 351) that face away from each other in an x direction (a direction perpendicular to the z direction). The end surfaces (341, 351) are exposed from respective side surfaces of the sealing resin that face in the x direction. The second leads protrude outward in a y direction from two side surfaces of the sealing resin that face in the y direction. The end surfaces (341, 351) of the parallel portions and the parts of the second leads 2 intersecting the sealing resin are located at the same position in the z direction. The first lead and the second leads are formed from a lead frame. The lead frame is subjected to a depression process, so that portions connected to the die pad are deformed in such a manner that the die pad is positioned on a lower side in the z direction. The portions deformed by the depression process correspond to the inclined portions (343, 353). The sealing resin is formed by transfer molding. When the sealing resin is formed, the parallel portions and the corresponding portions of the second leads, which are located at the same position in the z direction, are sandwiched between mold halves from both sides in the z direction, and fluidized resin is injected into the cavity. In the semiconductor device of JP-A-2022-143166, the bent-shaped fixing portions are connected to the die pad, thus allowing a reverse surface of the die pad to be exposed from a bottom surface of the sealing resin. This improves the heat dissipation of the semiconductor device.

In the above configuration, increasing the size of the die pad in plan view requires increasing the bending angle of each inclined portion (343, 353) which is a bent portion. However, increasing the bending angle of each inclined portion may cause cracks or fractures in the inclined portion (the lead frame). In addition, there is a risk of cracks or other defects in the portion of the sealing resin located between the fixing portions and the resin bottom surface. Since these constraints exist when increasing the size of the die pad, it has been difficult to increase the size of the die pad on which the semiconductor element is mounted, relative to the package size of the semiconductor device.

### BRIEF DESCRIPTION OF THE DRAWINGS

FIG. 1 is a perspective view showing a semiconductor device according to a first embodiment of the present disclosure.

FIG. 2 is a perspective view showing the semiconductor device according to the first embodiment of the present disclosure.

FIG. 3 is a plan view showing the semiconductor device according to the first embodiment of the present disclosure.

FIG. 4 is a front view showing the semiconductor device according to the first embodiment of the present disclosure.

FIG. 5 is a side view showing the semiconductor device according to the first embodiment of the present disclosure.

FIG. 6 is a bottom view showing the semiconductor device according to the first embodiment of the present disclosure.

FIG. 7 is a plan view corresponding to FIG. 3, with a sealing resin shown transparent.

FIG. 8 is a cross-sectional view taken along line VIII-VIII in FIG. 7.

FIG. 9 is a cross-sectional view taken along line IX-IX in FIG. 7.

FIG. 10 is a partial plan view showing an example of a lead frame used in a method for manufacturing the semiconductor device according to the first embodiment of the present disclosure.

FIG. 11 is a perspective view for explaining a mold used in a method for manufacturing the semiconductor device according to the first embodiment of the present disclosure.

FIG. 12 is a front view for explaining the mold used in the method for manufacturing the semiconductor device according to the first embodiment of the present disclosure.

FIG. 13 is a perspective view showing a semiconductor device according to a first variation of the first embodiment.

FIG. 14 is a perspective view showing the semiconductor device according to the first variation of the first embodiment.

FIG. 15 is a plan view showing the semiconductor device according to the first variation of the first embodiment, with a sealing resin shown transparent.

FIG. 16 is a cross-sectional view taken along line XVI-XVI in FIG. 15.

FIG. 17 is a cross-sectional view taken along line XVII-XVII in FIG. 15.

FIG. 18 is a perspective view showing a semiconductor device according to a second variation of the first embodiment.

FIG. 19 is a plan view showing the semiconductor device according to the second variation of the first embodiment.

FIG. 20 is a front view showing the semiconductor device according to the second variation of the first embodiment.

FIG. 21 is a side view showing the semiconductor device according to the second variation of the first embodiment.

FIG. 22 is a plan view corresponding to FIG. 19, with a sealing resin shown transparent.

FIG. 23 is a cross-sectional view taken along line XXIII-XXIII in FIG. 22.

FIG. 24 is a plan view showing a semiconductor device according to a third variation of the first embodiment, with a sealing resin shown transparent.

FIG. 25 is a cross-sectional view taken along line XXV-XXV in FIG. 24.

FIG. 26 is a cross-sectional view taken along line XXVI-XXVI in FIG. 24.

### DETAILED DESCRIPTION OF EMBODIMENTS

The following describes preferred embodiments of the present disclosure in detail with reference to the drawings.

The terms such as “first”, “second” and “third” in the present disclosure are used merely as labels, and are not intended to impose orders on the elements accompanied with these terms.

In the present disclosure, the phrases “an object A is formed in an object B” and “an object A is formed on an object B” include, unless otherwise specified, “an object A is formed directly in/on an object B” and “an object A is formed in/on an object B with another object interposed between the object A and the object B”. Similarly, the phrases “an object A is disposed in an object B” and “an object A is disposed on an object B” include, unless otherwise specified, “an object A is disposed directly in/on an object B” and “an object A is disposed in/on an object B with another object interposed between the object A and the object B”. Similarly, the phrase “an object A is located on an object B” includes, unless otherwise specified, “an object A is located on an object B in contact with the object B” and “an object A is located on an object B with another object interposed between the object A and the object B”. Further, the phrase “an object A overlaps with an object B as viewed in a certain direction” includes, unless otherwise specified, “an object A overlaps with the entirety of an object B” and “an object A overlaps with a part of an object B”. Further, the phrase “a plane A faces (a first side or a second side) in a direction B” in the present disclosure is not limited to the case where the angle of the plane A with respect to the direction B is 90°, but also includes the case where the plane A is inclined to the direction B.

### First Embodiment

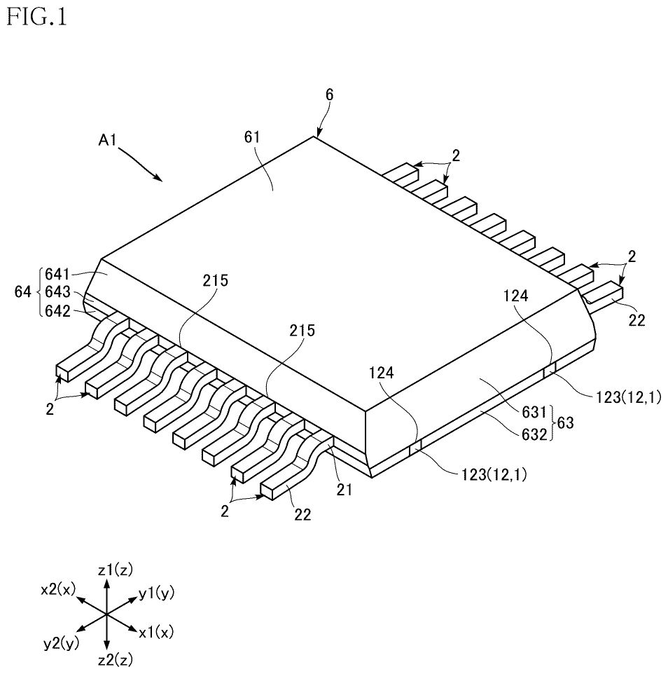

FIGS. 1 to 9 show a semiconductor device according to a first embodiment of the present disclosure. A semiconductor device A1 of the present embodiment includes a first lead 1, a plurality of second leads 2, a semiconductor element 3, a plurality of wires 4, and a sealing resin 6. The semiconductor device A1 is provided in a small outline package (SOP). Note that the package type of the semiconductor device A1 is not limited to an SOP.

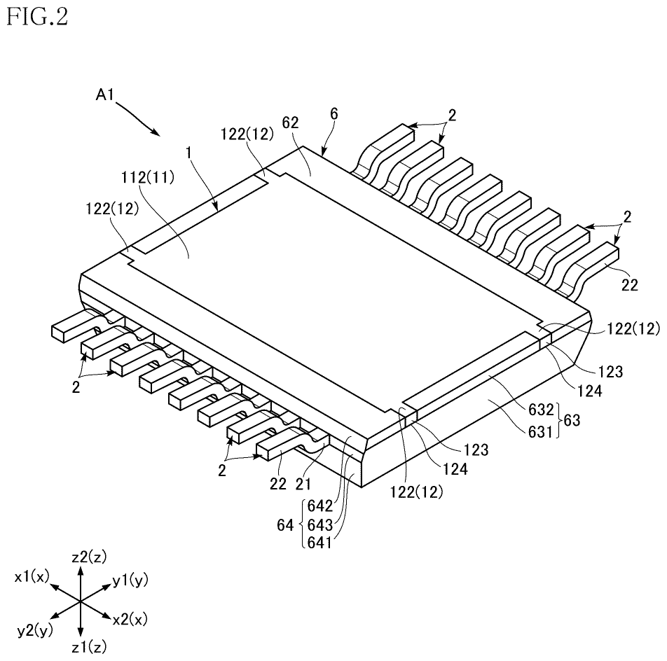

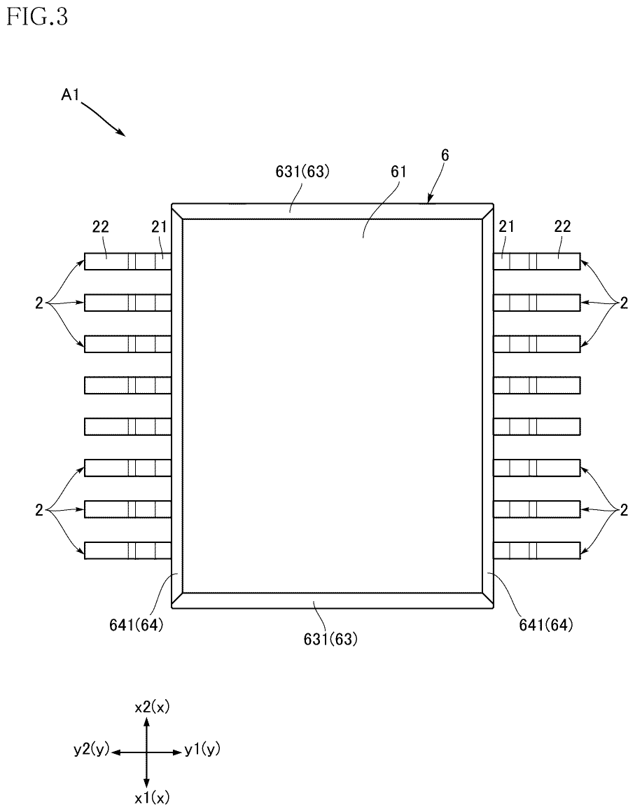

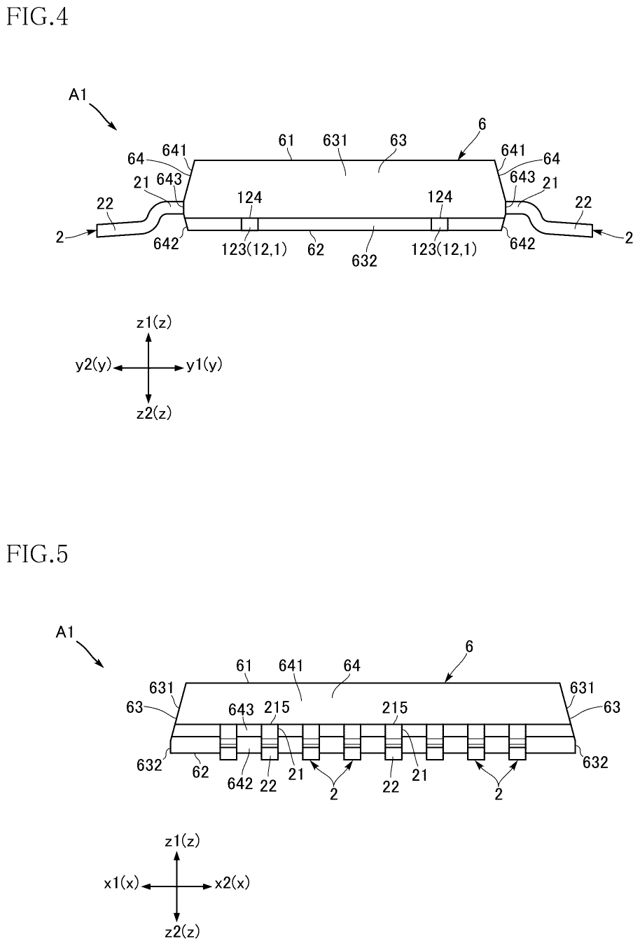

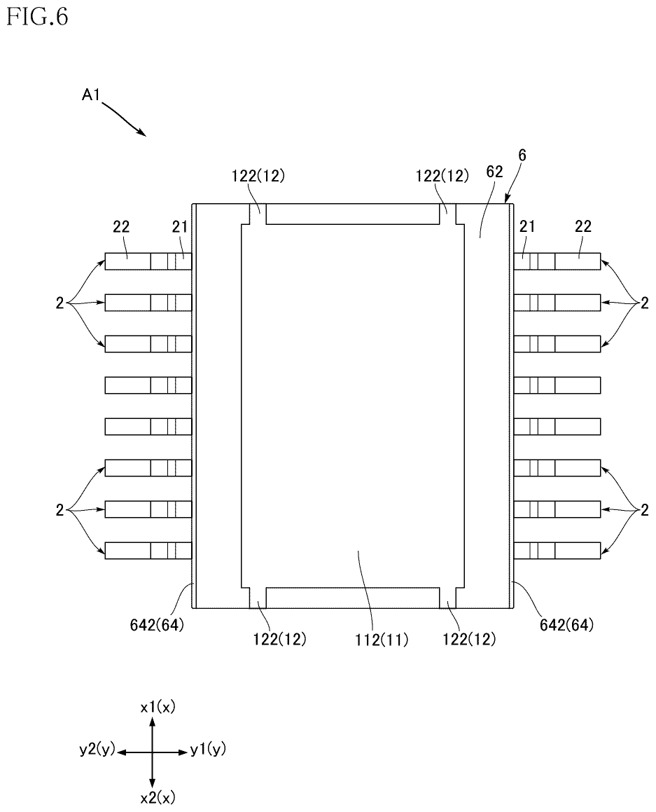

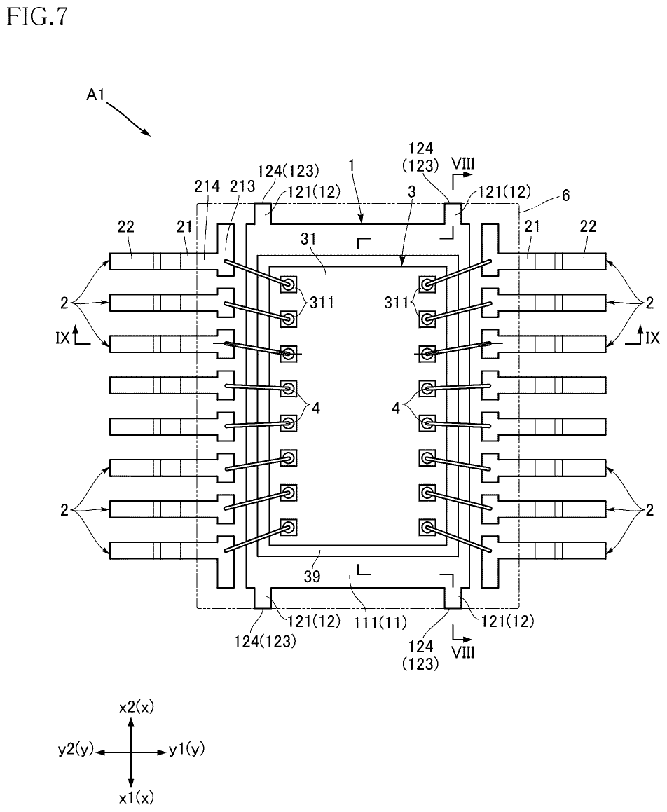

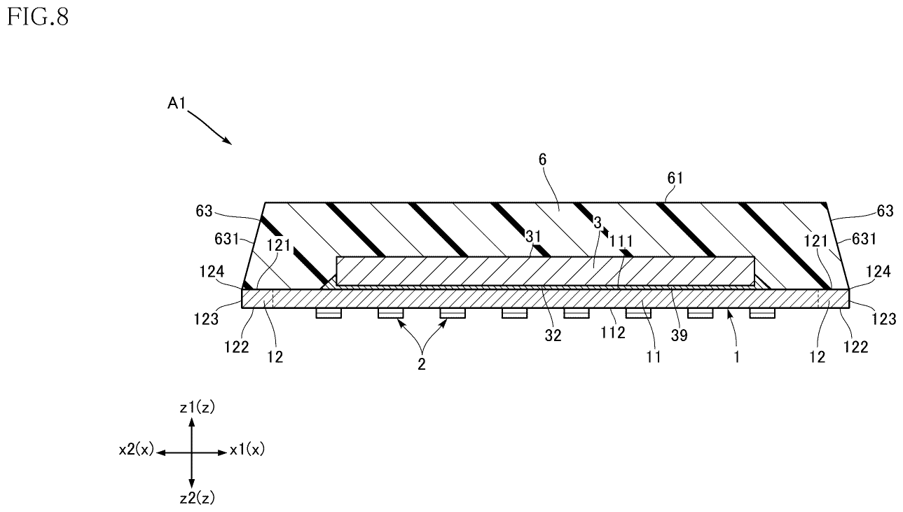

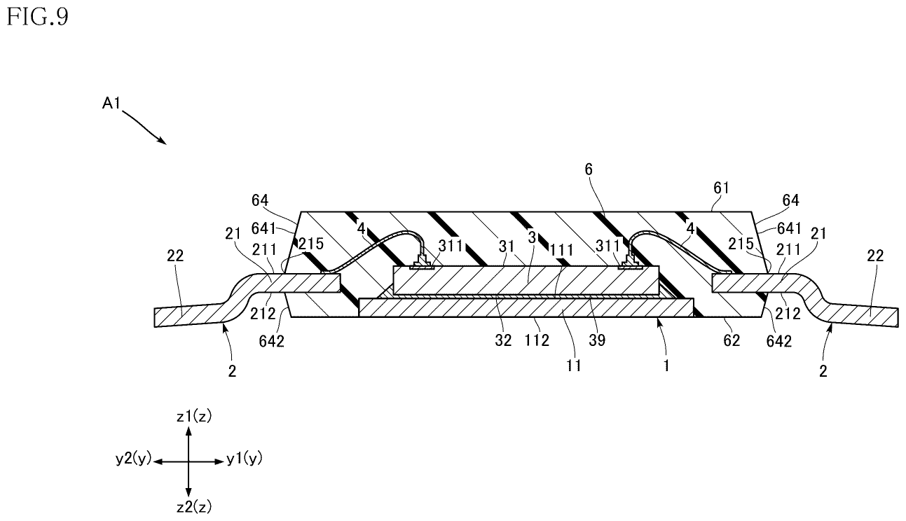

FIG. 1 is a perspective view showing the semiconductor device A1. FIG. 2 is a perspective view showing the semiconductor device A1 in a state where the semiconductor device A1 is turned upside down. FIG. 3 is a plan view showing the semiconductor device A1. FIG. 4 is a front view showing the semiconductor device A1. FIG. 5 is a side view showing the semiconductor device A1. FIG. 6 is a bottom view showing the semiconductor device A1. FIG. 7 is a plan view showing the semiconductor device A1, with the sealing resin 6 shown transparent. FIG. 8 is a cross-sectional view taken along line VIII-VIII in FIG. 7. FIG. 9 is a cross-sectional view taken along line IX-IX in FIG. 7. In FIG. 7, the sealing resin 6 is indicated by an imaginary line (two-dot chain line).

In the description of the semiconductor device A1, the thickness direction of the semiconductor element 3 is referred to as a “thickness direction z”. A direction perpendicular to the thickness direction z (the vertical direction in FIG. 3) is referred to as a “first direction x”. The direction perpendicular to the thickness direction z and the first direction x (the horizontal direction in FIG. 3) is referred to as a “second direction y”. As shown in FIG. 3, the semiconductor device A1 has a rectangular (or substantially rectangular) shape as viewed in the thickness direction z (in plan view).

The first lead 1 supports the semiconductor element 3, and is formed by cutting and bending a metal plate material such as copper (Cu) or a copper alloy. As shown in FIGS. 1, 2, 4, and 6 to 9, the first lead 1 of the present embodiment has a first portion 11 and four second portions 12. The thickness of the first lead 1 is not particularly limited, and may be in the range of 0.1 mm to 0.5 mm, with a specific example being approximately 0.15 mm.

The first portion 11 is a portion on which the semiconductor element 3 is mounted. The shape of the first portion 11 is not particularly limited. In the illustrated example, the first portion 11 has a rectangular shape. The first portion 11 has a first obverse surface 111 and a first reverse surface 112. The first obverse surface 111 faces a z1 side in the thickness direction z. The first obverse surface 111 is covered with the sealing resin 6. The first reverse surface 112 faces a z2 side in the thickness direction z. The first reverse surface 112 is exposed from the sealing resin 6. The size of the first portion 11 is not particularly limited. In the example where the first portion 11 has a rectangular shape, one side thereof may have a length of approximately 1.5 mm to 5.0 mm.

The four second portions 12 are located on the outer sides of the first portion 11 in the first direction x (the x1 side and the x2 side in the first direction x). Specifically, two of the four second portions 12 are located on the x1 side in the first direction x of the first portion 11, and the other two second portions 12 are located on the x2 side in the first direction x of the first portion 11. The four second portions 12 are connected to the first portion 11. The two second portions 12 located on the x1 side in the first direction x of the first portion 11 are spaced apart from each other in the second direction y, and are connected to the respective portions of the first portion 11 near the ends thereof in the second direction y. The two second portions 12 located on the x2 side in the first direction x of the first portion 11 are spaced apart from each other in the second direction y, and are connected to the respective portions of the first portion 11 near the ends thereof in the second direction y. The shape of each second portion 12 is not particularly limited. In the illustrated example, each second portion 12 has a shape having a constant (or substantially constant) dimension (width) in the second direction y. The dimension of each second portion 12 in the second direction y is not particularly limited, and may be approximately 0.2 mm, for example. Each second portion 12 has a second obverse surface 121, a second reverse surface 122, and a first end surface 123.

The second obverse surface 121 faces the z1 side in the thickness direction z. The second obverse surface 121 is covered with the sealing resin 6. The second reverse surface 122 faces the z2 side in the thickness direction z. The second reverse surface 122 is exposed from the sealing resin 6. The first end surface 123 faces outward in the first direction x. The first end surface 123 is connected to the second obverse surface 121 and the second reverse surface 122, and is exposed from the sealing resin 6 (a first resin side surface 63 described below).

As shown in FIGS. 2, 4, 7, and 8, the second portions 12 are located at the same position as the first portion 11 in the thickness direction z. More specifically, the second obverse surfaces 121 are located at the same position as the first obverse surface 111 of the first portion 11 in the thickness direction z, and are continuous with the first obverse surface 111. The second reverse surfaces 122 are located at the same position as the first reverse surface 112 of the first portion 11 in the thickness direction z, and are continuous with the first reverse surface 112.

Unlike the illustrated example, the first lead 1 may be provided with two second portions 12. When the first lead 1 has two second portions 12, one of the second portions 12 is located on the x1 side in the first direction x of the first portion 11, and the other second portion 12 is located on the x2 side in the first direction x of the first portion 11. In this case, each of the two second portions 12 is connected to the center of the first portion 11 in the second direction y.

The second leads 2 are used as terminals for mounting the semiconductor device A1 onto a wiring board or the like, and are electrically connected to the semiconductor element 3. The second leads 2 are formed by cutting and bending a metal plate material such as copper or a copper alloy. As shown in FIGS. 1 to 9, the second leads 2 are spaced apart from the first portion 11 in the second direction y. The second leads 2 are located on the opposite sides of the first portion 11 (the first lead 1) in the second direction y (the y1 side and the y2 side in the second direction y). The second leads 2 are spaced part from each other in the first direction x. In the present embodiment, the second leads 2 are disposed at equal intervals in the first direction x. Each of the second leads 2 in the present embodiment has a lead portion 21 and a terminal portion 22. The thickness of each second lead 2 is not particularly limited, and may be in the range of 0.1 mm to 0.5 mm, with a specific example being approximately 0.15 mm.

The lead portion 21 is located on the z1 side in the thickness direction z relative to the first portion 11. The lead portion 21 has a third obverse surface 211 and a third reverse surface 212. The third obverse surface 211 faces the z1 side in the thickness direction z. The third reverse surface 212 faces the z2 side in the thickness direction z. The third obverse surface 211 is located on the z1 side in the thickness direction z relative to the first obverse surface 111 and the second obverse surface 121. The third reverse surface 212 is located on the z1 side in the thickness direction z relative to the first reverse surface 112.

In the present embodiment, the lead portion 21 has a pad portion 213 and a strip portion 214. The pad portion 213 is a portion to which a wire 4 is bonded. The strip portion 214 is connected to the pad portion 213, and is located on the side opposite to the first portion 11 relative to the pad portion 213 in the second direction y. The dimension of the pad portion 213 in the first direction x is larger than the dimension of the strip portion 214 in the first direction x. The dimension of the strip portion 214 in the first direction x may be approximately 0.2 mm, for example. In the lead portion 21, a part of the strip portion 214 and the pad portion 213 are covered with the sealing resin 6, and the remaining part of the strip portion 214 is exposed from the sealing resin 6 (a second resin side surface 64 described below).

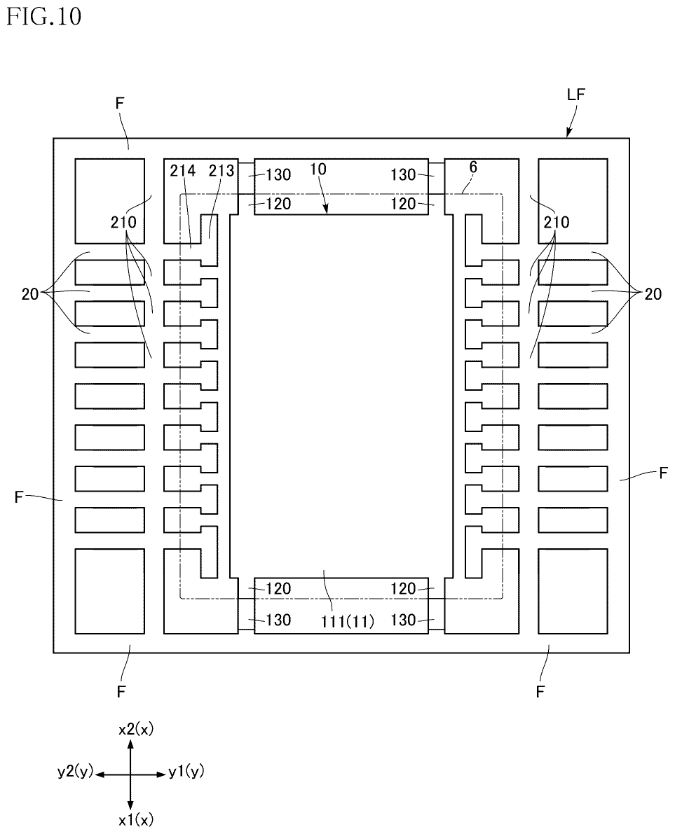

The terminal portion 22 is connected to the end of the lead portion 21 that is farthest from the first portion 11 in the second direction y, and is located outward from the lead portion 21 in the second direction y. The terminal portion 22 has a rectangular shape elongated in the second direction y in plan view. As shown in FIGS. 4 and 9, the terminal portion 22 is bent into a gull-wing shape as viewed in the first direction x. The terminal portion 22 is located on the z2 side in the thickness direction z relative to the lead portion 21 in the thickness direction z. The tip of the terminal portion 22 is a portion that is bonded to a wiring board or the like when the semiconductor device A1 is mounted thereon. The dimension of the terminal portion 22 in the first direction x may be approximately 0.2 mm, for example. The first lead 1 and the second leads 2 are formed from a lead frame LF (see FIG. 10) described below.

The semiconductor element 3 performs an electrically significant function in the semiconductor device A1. The semiconductor element 3 is not limited to a specific example, and may be a large scale integration (LSI) or an integrated circuit (IC). The semiconductor element 3 is not limited to a particular shape or size. As shown in FIG. 7, the semiconductor element 3 of the present embodiment may have a rectangular shape smaller than the first portion 11 as viewed in the thickness direction z. As shown in FIGS. 8 and 9, the semiconductor element 3 has an element obverse surface 31 and an element reverse surface 32. The element obverse surface 31 faces the z1 side in the thickness direction z. The element reverse surface 32 faces the z2 side in the thickness direction z.

The element obverse surface 31 is provided with a plurality of electrode pads 311. The electrode pads 311 are arranged in two lines in the first direction x on the element obverse surface 31, for example. The element reverse surface 32 faces the first obverse surface 111 of the first portion 11, and is bonded to the first obverse surface 111 via a bonding material 39. Thus, the semiconductor element 3 is supported by the first obverse surface 111 via the bonding material 39. The bonding material 39 may be a conductive bonding material such as solder or silver (Ag) paste, or may be an insulating bonding material such as an epoxy adhesive.

The wires 4 electrically connect the semiconductor element 3 and the second leads 2. As shown in FIG. 7, the wires 4 are respectively bonded to the electrode pads 311 of the semiconductor element 3 and the pad portions 213 of the lead portions 21 of the second leads 2. The wires 4 are made of gold (Au), aluminum (A1), or copper, for example. In the present embodiment, the wires 4 are made of gold in the present embodiment.

The sealing resin 6 covers a part of the first lead 1, parts of the second leads 2, the semiconductor element 3, and the wires 4. The sealing resin 6 is made of an insulating resin, such as a black epoxy resin containing fillers. As shown in FIGS. 1 to 9, the sealing resin 6 of the present embodiment has a resin obverse surface 61, a resin reverse surface 62, two first resin side surfaces 63, and two second resin side surfaces 64.

The resin obverse surface 61 faces the z1 side in the thickness direction z. The resin reverse surface 62 faces the z2 side in the thickness direction z. In the present embodiment, the resin obverse surface 61 has a rectangular shape. The first reverse surface 112 of the first portion 11 and the second reverse surfaces 122 of the four second portions 12 are exposed from the resin reverse surface 62. The outer peripheral edge of the resin reverse surface 62 has a rectangular shape, and the area ratio of the first reverse surface 112 to the area surrounded by the outer peripheral edge of the resin reverse surface 62 is at least 60% and at most 85%.

The two second resin side surfaces 64 are located between the resin obverse surface 61 and the resin reverse surface 62 and on the respective sides in the second direction y (the y1 side and the y2 side in the second direction y). In the present embodiment, each of the second resin side surfaces 64 has a first region 641, a second region 642, and a third region 643.

As shown in FIGS. 4, 5, and 9, the first region 641 is connected to the resin obverse surface 61, and is located between the resin obverse surface 61 and the third obverse surfaces 211 of lead portions 21 in the thickness direction z. The first region 641 is inclined to the thickness direction z. The second region 642 is connected to the resin reverse surface 62, and is located between the third reverse surface 212 and the resin reverse surface 62 in the thickness direction z. The second region 642 is inclined to the thickness direction z.

The third region 643 is located between the first region 641 and the second region 642 in the thickness direction z. In addition, the third region 643 is located between third obverse surfaces 211 and third reverse surfaces 212 in the thickness direction z, and parts of lead portions 21 (parts of second leads 2) protrude from the third region 643. As shown in FIGS. 1, 5, and 9, each of the lead portions 21 (the second leads 2) has a second edge 215. The second edge 215 is an edge of the lead portion 21 (the second lead 2) on the z1 side in the thickness direction z, and is located in an area where the lead portion 21 intersects a second resin side surface 64. The second edge 215 is at the same position as the third obverse surface 211 in the thickness direction z.

The two first resin side surfaces 63 are located between the resin obverse surface 61 and the resin reverse surface 62 and on the respective sides in the first direction x (the x1 side and the x2 side in the first direction x). In the present embodiment, each of the first resin side surfaces 63 has a fourth region 631 and a fifth region 632.

As shown in FIGS. 4, 5, and 8, the fourth region 631 is connected to the resin obverse surface 61, and is located between the resin obverse surface 61 and the second obverse surfaces 121 of second portions 12 in the thickness direction z. The fourth region 631 is inclined to the thickness direction z.

The fifth region 632 is connected to the end of the fourth region 631 on the z2 side in the thickness direction z, and is located between the fourth region 631 and the resin reverse surface 62. In addition, the fifth region 632 is located between second obverse surfaces 121 and second reverse surfaces 122 in the thickness direction z, and first end surfaces 123 are exposed from the fifth region 632. As shown in FIGS. 4 and 5, the fifth region 632 is located on the z2 side in the thickness direction z relative to the third region 643. As shown in FIGS. 1, 4, and 8, each of the first end surfaces 123 has a first edge 124. The first edge 124 is an edge of the first end surface 123 on the z1 side in the thickness direction z. The first edge 124 is at the same position as the second obverse surface 121 in the thickness direction z. As described above, each of the third obverse surfaces 211 is located on the z1 side in the thickness direction z relative to the first obverse surface 111 and a second obverse surface 121. Each of the first edges 124 is located at the same position as a second obverse surface 121 in the thickness direction z, and is located on the z2 side in the thickness direction z relative to a second edge 215 located at the same position as a third obverse surface 211.

FIG. 10 shows a lead frame LF, which is an example of a member used in the manufacturing of the semiconductor device A1. The lead frame LF includes a frame F, and a lead 10, a plurality of leads 20, and a plurality of tie bars 210 that are connected to the frame F. A large part of the lead 10 and a large part of each lead 20 are cut off from the lead frame LF to form the first lead 1 and the second leads 2. The lead 10 has the first portion 11, four second portions 120, and four bent portions 130. The second portions 120 will be formed into the second portions 12. The lead frame LF includes portions connected to the frame F and the second portions 120, and these portions are deformed by a depression process so that the first portion 11 and the second portions 120 are located on the z2 side in the thickness direction z relative to the frame F. The bent portions 130 are the portions deformed by the depression process. The lead frame LF is cut along the boundaries between the second portions 120 and the bent portions 130. The frame F, the bent portions 130, and the tie bars 210 of the lead frame LF do not constitute the semiconductor device A1. Note that the first obverse surface 111 of the first portion 11 and the pad portions 213 may be provided with plating layers, such as those made of silver or nickel (Ni), as necessary. After the semiconductor element 3 is mounted onto the lead frame LF and the wires 4 are bonded, the sealing resin 6 is formed.

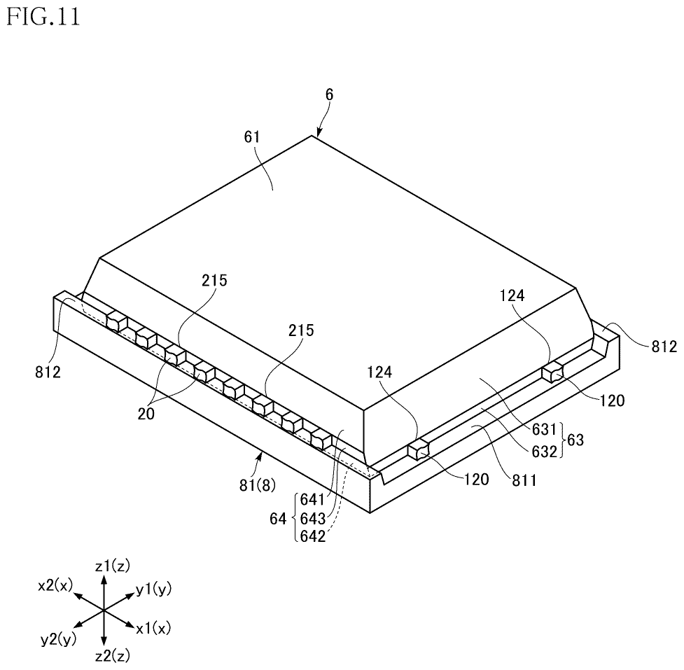

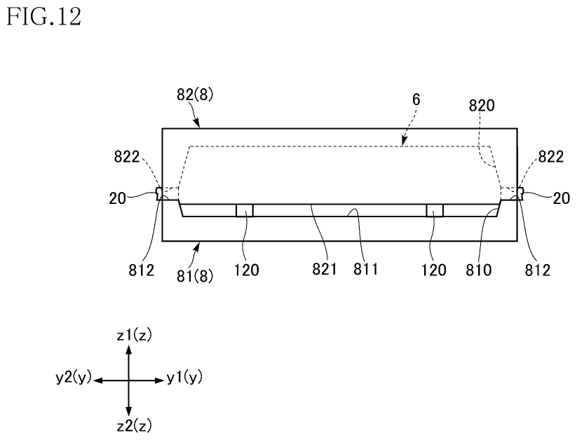

The sealing resin 6 is formed by transfer molding, for example. FIGS. 11 and 12 show an example a schematic configuration of a mold used to form the sealing resin 6. When the sealing resin 6 is formed, the lead frame LF is housed in a mold 8 having a plurality of cavities. The mold 8 includes a lower mold 81 having a cavity 810 and an upper mold 82 having a cavity 820, for example, and parts (parts of the lead 10 and the leads 20) of the lead frame LF that are covered by the sealing resin 6 in the semiconductor device A1 are housed in the cavities 810 and 820.

The lower mold 81 has mating surfaces 811 and mating surfaces 812. The mating surfaces 811 are located at positions corresponding to the first resin side surfaces 63 of the sealing resin 6, and the mating surfaces 812 are located at positions corresponding to the second resin side surfaces 64. The mating surfaces 811 corresponding to the first resin side surfaces 63 are located at different positions in the thickness direction z from the mating surfaces 812 corresponding to the second resin side surfaces 64. The mating surfaces 811 are offset to the z2 side in the thickness direction z from the mating surfaces 812. The upper mold 82 has mating surfaces 821 and mating surfaces 822. The mating surfaces 821 are located at positions corresponding to the first resin side surfaces 63, and the mating surfaces 822 are located at positions corresponding to the second resin side surfaces 64. The mating surfaces 821 corresponding to the first resin side surfaces 63 are located at different positions in the thickness direction z from the mating surfaces 822 corresponding to the second resin side surfaces 64. The mating surfaces 821 are offset to the z2 side in the thickness direction z from the mating surfaces 822. When the lead frame LF is placed in the mold 8, the second portions 120 are sandwiched between the mating surfaces 811 of the lower mold 81 and the mating surfaces 821 of the upper mold 82, and the leads 20 are sandwiched between the mating surfaces 821 of the lower mold 81 and the mating surfaces 822 of the upper mold 82.

In a step of forming the sealing resin 6, fluidized resin is poured into the cavities 810 and 820 of the mold 8 to fill the cavities 810 and 820, and then the resin is solidified. Then, singulation is performed through punching and other processes, and thereby the lead 10 and the leads 20 (which will be formed into the first lead 1 and the second leads 2) that are connected to each other by the frame F and the tie bars 210 are separated appropriately. Next, the portions of the second leads 2 that protrude from the sealing resin 6 are subjected to a bending process. The semiconductor device A1 is manufactured through the steps described above.

The following describes advantages of the semiconductor device A1.

In the semiconductor device A1, the first lead 1 has the first end surfaces 123 that are located on the respective sides in the first direction x and exposed from the respective first resin side surfaces 63. Each of the first end surfaces 123 has a first edge 124 located on the z1 side in the thickness direction z. The second leads 2 protrude outward from the two second resin side surfaces 64 in the second direction y. Each of the second leads 2 has a second edge 215 located on the z1 side in the thickness direction z, in an area where the second lead 2 intersects a second resin side surface 64. The first edges 124 of the first lead 1 are located on the z2 side in the thickness direction z relative to the second edges 215 in the thickness direction z. With this configuration, the first lead 1 on which the semiconductor element 3 is mounted has no bent portion deformed in the thickness direction z by a depression process. This makes it possible to eliminate disadvantages that may arise when a bent portion is formed in a lead by a depression process, and to increase the size of the portion (the first portion 11) on which the semiconductor element 3 is mounted.

The first lead 1 includes the first portion 11 on which the semiconductor element 3 is mounted, and the second portions 12 that are connected to the first portion 11 and located on the outer sides of the first portion 11 in the first direction x. Each of the second portions 12 has a first end surface 123. According to such a configuration, for example, in the lead frame LF with which the first lead 1 and the second leads 2 are formed, it is possible to form the bent portions 130 by a depression process between the frame F and the second portions 120 connected to the outer sides of the first portion 11 in the first direction x. Thus, the semiconductor device A1 can be appropriately manufactured without including any bent portions formed by a depression process, by cutting the boundaries between the second portions 120 and the bent portions 130 to singulate the semiconductor device A1.

The first portion 11 has the first obverse surface 111 facing the z1 side in the thickness direction z, and the first reverse surface 112 facing the z2 side in the thickness direction z. The semiconductor element 3 is supported by the first obverse surface 111. The first reverse surface 112 is exposed from the resin reverse surface 62. With this configuration, the heat dissipation of the semiconductor device A1 can be improved. In the semiconductor device A1, it is possible to increase the size of the first portion 11 on which the semiconductor element 3 is mounted, as described above. This is more preferable for 35 improving the heat dissipation of the semiconductor device A1.

Each of the second portions 12 has a second obverse surface 121 facing the z1 side in the thickness direction z, and a second reverse surface 122 facing the z2 side in the thickness direction z. The second obverse surface 121 is located at the same position as the first obverse surface 111 of the first portion 11 in the thickness direction z. The second reverse surface 122 is located at the same position as the first reverse surface 112 of the first portion 11 in the thickness direction z, and is exposed from the resin reverse surface 62. With this configuration, the first portion 11 and the second portions 12 connected thereto can be easily formed. Furthermore, since the second reverse surfaces 122, as well as the first reverse surface 112, are exposed from the resin reverse surface 62, it is possible to further improve the heat dissipation of the semiconductor device A1.

Each second resin side surface 64 of the sealing resin 6 has a first region 641, a second region 642, and a third region 643. The first region 641 is connected to the resin obverse surface 61, and the second region 642 is connected to the resin reverse surface 62. The third region 643 is located between the first region 641 and the second region 642 in the thickness direction z. Parts of second leads 2 protrude from the third region 643. Each of the first resin side surfaces 63 has a fourth region 631 and a fifth region 632. The fourth region 631 is connected to the resin obverse surface 61, and the fifth region 632 is connected to the end of the fourth region 631 on the z2 side in the thickness direction z and to the resin reverse surface 62. The fifth region 632 is offset to the z2 side in the thickness direction z relative to the third region 643. First end surfaces 123 are exposed from the fifth region 632. The semiconductor device A1 including the sealing resin 6 having such a configuration can be manufactured by forming the sealing resin 6 by the transfer molding described above.

### First Variation of First Embodiment

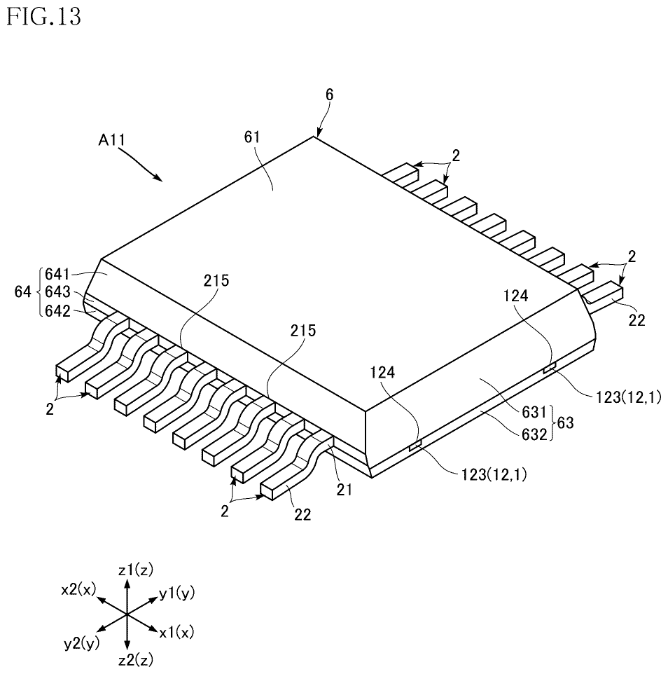

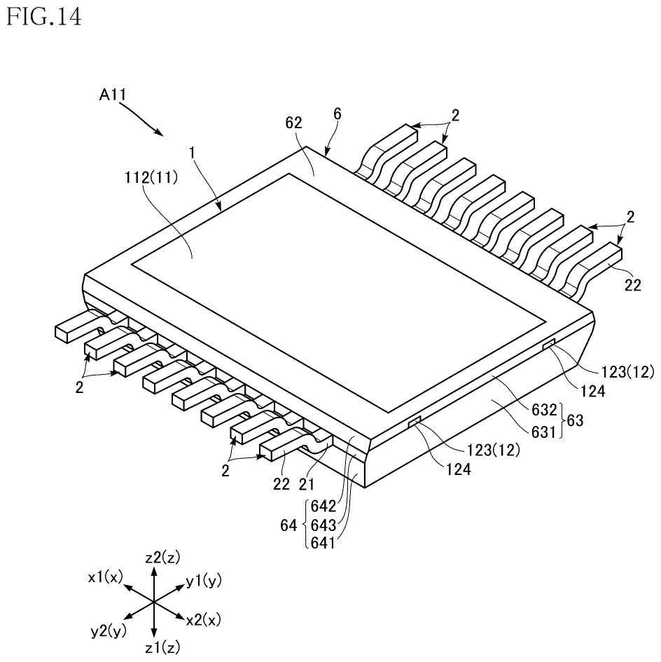

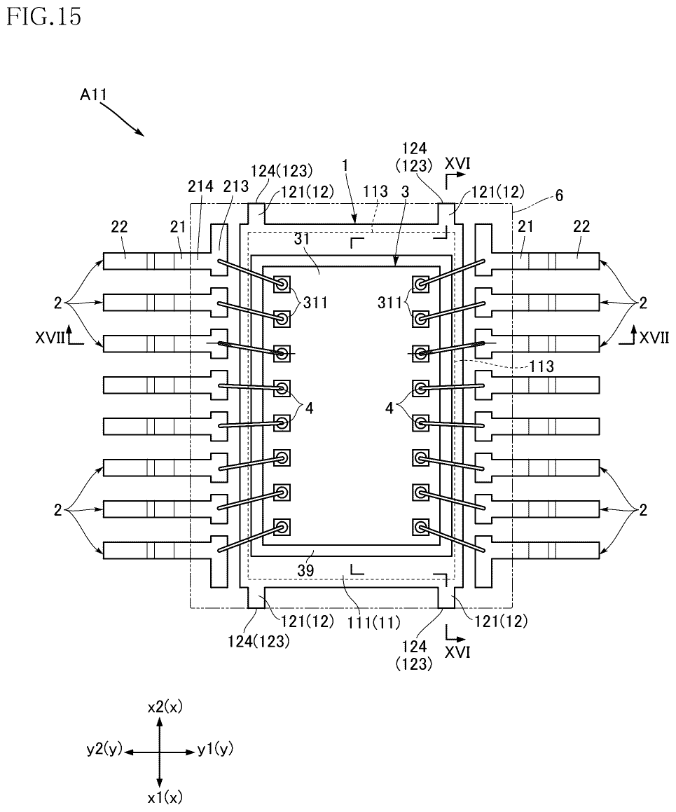

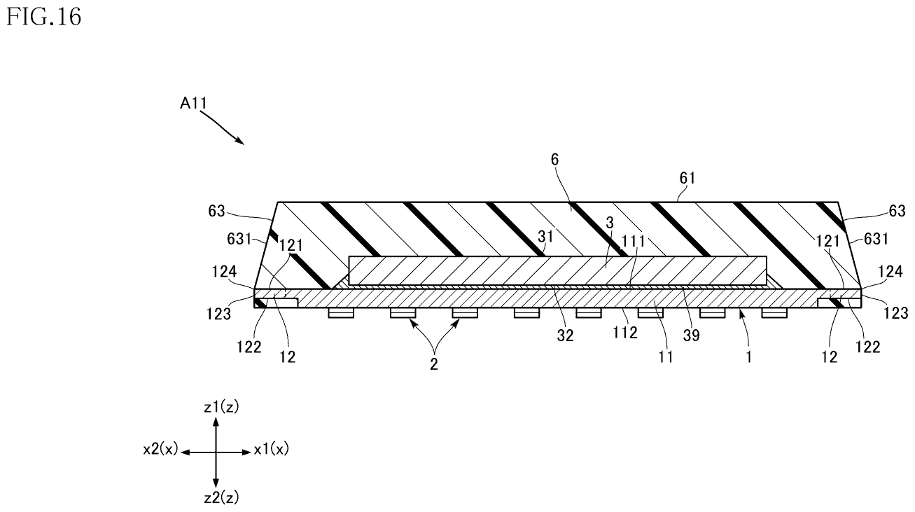

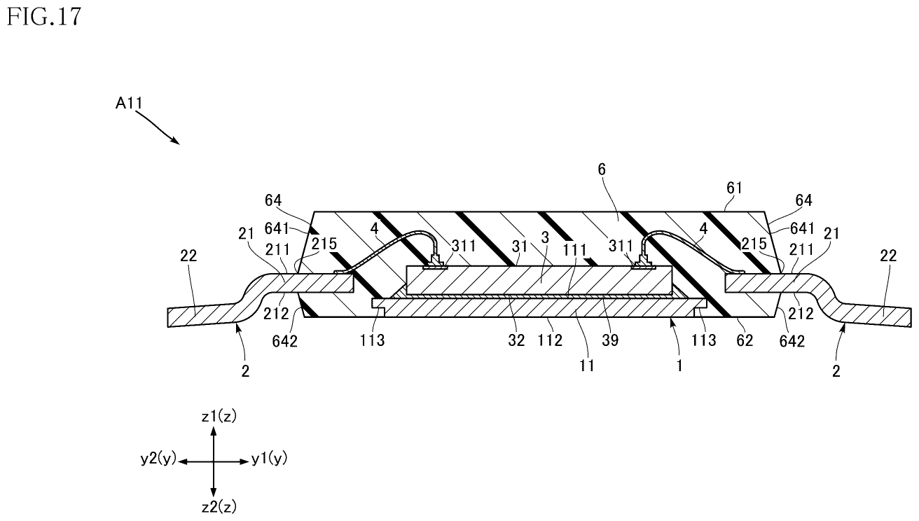

FIGS. 13 to 17 show a semiconductor device according to a first variation of the first embodiment. FIG. 13 is a perspective view showing a semiconductor device A11 of the present variation. FIG. 14 is a perspective view showing the semiconductor device A11 in a state where the semiconductor device A11 is turned upside down. FIG. 15 is a plan view showing the semiconductor device A11, with the sealing resin 6 shown transparent. FIG. 16 is a cross-sectional view taken along line XVI-XVI in FIG. 15. FIG. 17 is a cross-sectional view taken along line XVII-XVII in FIG. 15. In FIG. 15, the sealing resin 6 is indicated by an imaginary line (two-dot chain line). In FIG. 13 and the subsequent figures, the elements that are identical with or similar to those of the semiconductor device A1 in the above embodiment are designated by the same reference numerals as in the above embodiment, and the descriptions thereof are omitted as appropriate.

The semiconductor device A11 of the present variation is different from the semiconductor device A1 of the above embodiment in the configurations of the first portion 11 and the second portions 12. In the present variation, the first portion 11 has a reverse-surface recess 113. The reverse-surface recess 113 is formed at the periphery of the first portion 11 as viewed in the thickness direction z, and is recessed to the z1 side in the thickness direction z from the first reverse surface 112. The reverse-surface recess 113 is covered with the sealing resin 6. The second reverse surfaces 122 of the second portions 12 are located on the z1 side in the thickness direction z relative to the first reverse surface 112. The second reverse surface 122 is covered with the sealing resin 6. The reverse-surface recess 113 and the second reverse surfaces 122 having the configurations described above may be formed by a half-etching process on the reverse surface of the first lead 1.

In the semiconductor device A11 of the present variation, the first lead 1 has the first end surfaces 123 that are located on the respective sides in the first direction x and exposed from the respective first resin side surfaces 63. Each of the first end surfaces 123 has a first edge 124 located on the z1 side in the thickness direction z. The second leads 2 protrude outward from the two second resin side surfaces 64 in the second direction y. Each of the second leads 2 has a second edge 215 located on the z1 side in the thickness direction z, in an area where the second lead 2 intersects a second resin side surface 64. The first edges 124 of the first lead 1 are located on the z2 side in the thickness direction z relative to the second edges 215 in the thickness direction z. With this configuration, the first lead 1 on which the semiconductor element 3 is mounted has no bent portion deformed in the thickness direction z by a depression process. This makes it possible to eliminate disadvantages that may arise when a bent portion is formed in a lead by a depression process, and to increase the size of the portion (the first portion 11) on which the semiconductor element 3 is mounted.

The first portion 11 in the semiconductor device A11 has the reverse-surface recess 113. The reverse-surface recess 113 is formed at the periphery of the first portion 11 as viewed in the thickness direction z, and is recessed to the z1 side in the thickness direction z from the first reverse surface 112. The second reverse surfaces 122 of the second portions 12 are located on the z1 side in the thickness direction z relative to the first reverse surface 112, and are covered with the sealing resin 6. With this configuration, the reverse-surface recess 113 and the second reverse surfaces 122 are engaged with a part of the sealing resin 6, thus increasing the force with which the sealing resin 6 holds the first lead 1. In addition, the semiconductor device A11 has the same advantages as the semiconductor device A1 in the above embodiment within the range of the same configuration as that of the semiconductor device A1.

### Second Variation of First Embodiment

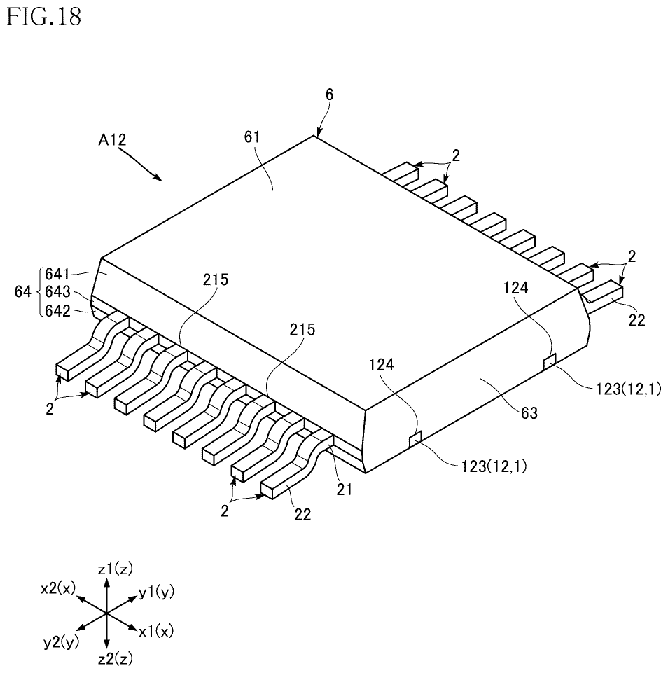

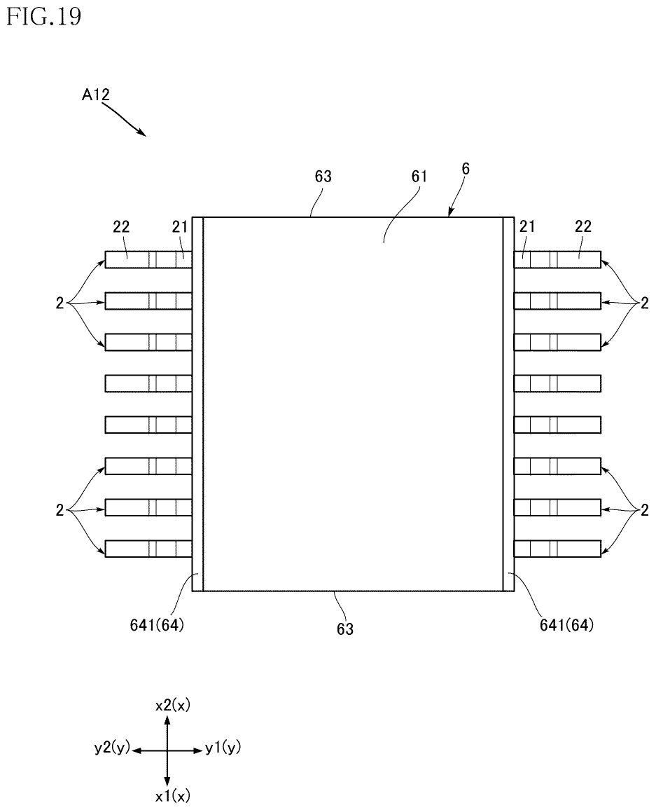

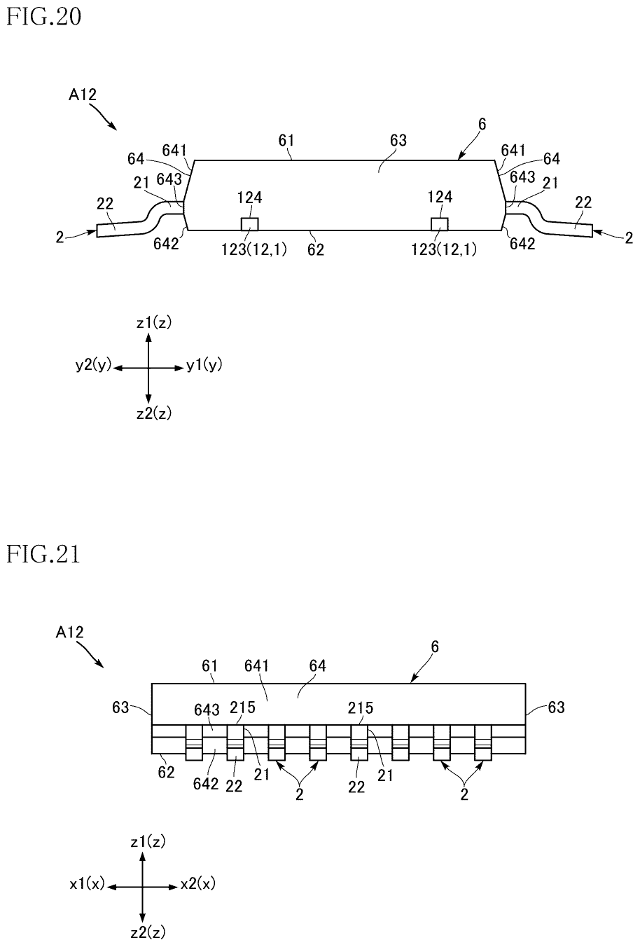

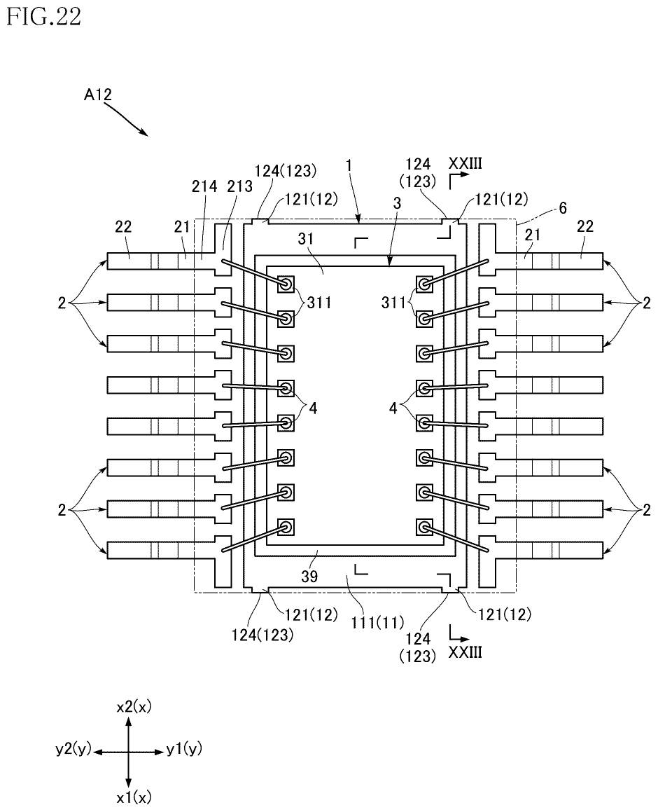

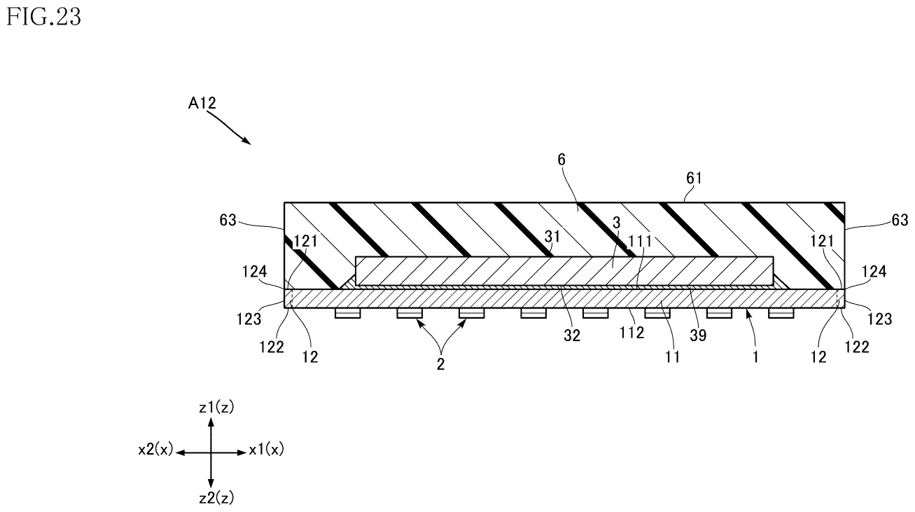

FIGS. 18 to 23 show a semiconductor device according to a second variation of the first embodiment. FIG. 18 is a perspective view showing a semiconductor device A12 of the present variation. FIG. 19 is a plan view showing the semiconductor device A12. FIG. 20 is a front view showing the semiconductor device A12. FIG. 21 is a side view showing the semiconductor device A12. FIG. 22 is a plan view corresponding to FIG. 19, with the sealing resin 6 shown transparent. FIG. 23 is a cross-sectional view taken along line XXIII-XXIII in FIG. 22. In FIG. 22, the sealing resin 6 is indicated by an imaginary line (two-dot chain line).

The semiconductor device A12 of the present variation is different from the semiconductor device A1 of the above embodiment mainly in the configurations of the two first resin side surfaces 63 of the sealing resin 6. In the present variation, each of the first resin side surfaces 63 is provided along a plane perpendicular to the first direction x. The first resin side surfaces 63 having such configurations may be formed by cutting with a blade after the sealing resin 6 is formed, during the manufacturing process of the semiconductor device A12.

In the semiconductor device A12 of the present variation, the first lead 1 has the first end surfaces 123 that are located on the respective sides in the first direction x and exposed from the respective first resin side surfaces 63. Each of the first end surfaces 123 has a first edge 124 located on the z1 side in the thickness direction z. The second leads 2 protrude outward from the two second resin side surfaces 64 in the second direction y. Each of the second leads 2 has a second edge 215 located on the z1 side in the thickness direction z, in an area where the second lead 2 intersects a second resin side surface 64. The first edges 124 of the first lead 1 are located on the z2 side in the thickness direction z relative to the second edges 215 in the thickness direction z. With this configuration, the first lead 1 on which the semiconductor element 3 is mounted has no bent portion deformed in the thickness direction z by a depression process. This makes it possible to eliminate disadvantages that may arise when a bent portion is formed in a lead by a depression process, and to increase the size of the portion (the first portion 11) on which the semiconductor element 3 is mounted. In addition, the semiconductor device A12 has the same advantages as the semiconductor device A1 in the above embodiment within the range of the same configuration as that of the semiconductor device A1.

### Third Variation of First Embodiment

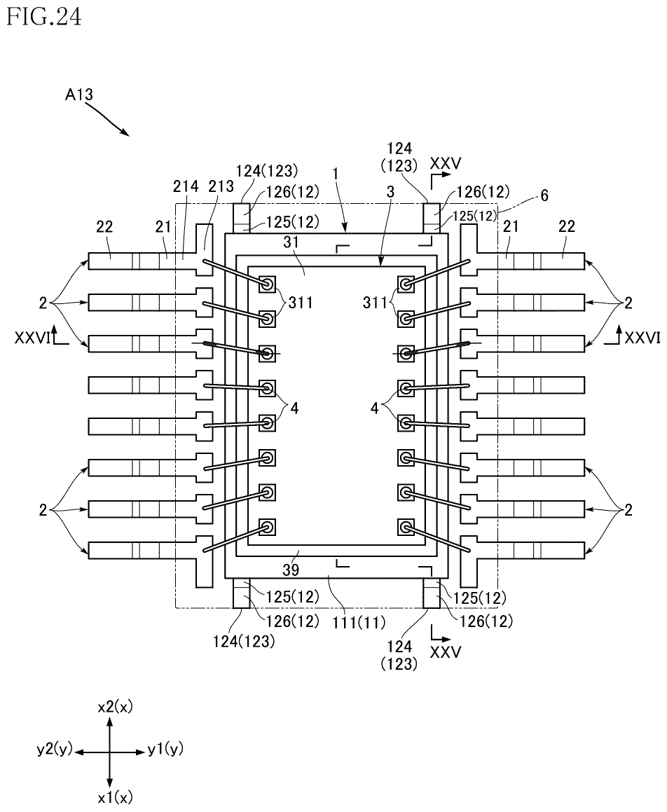

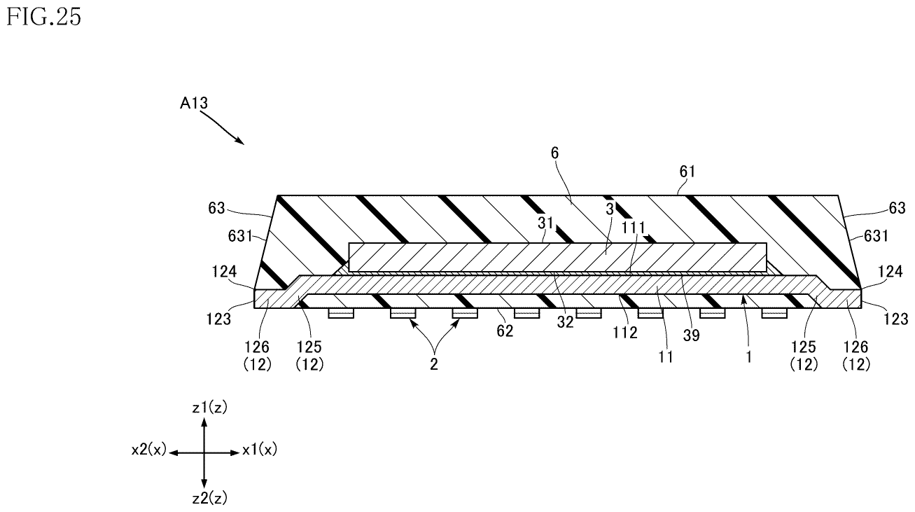

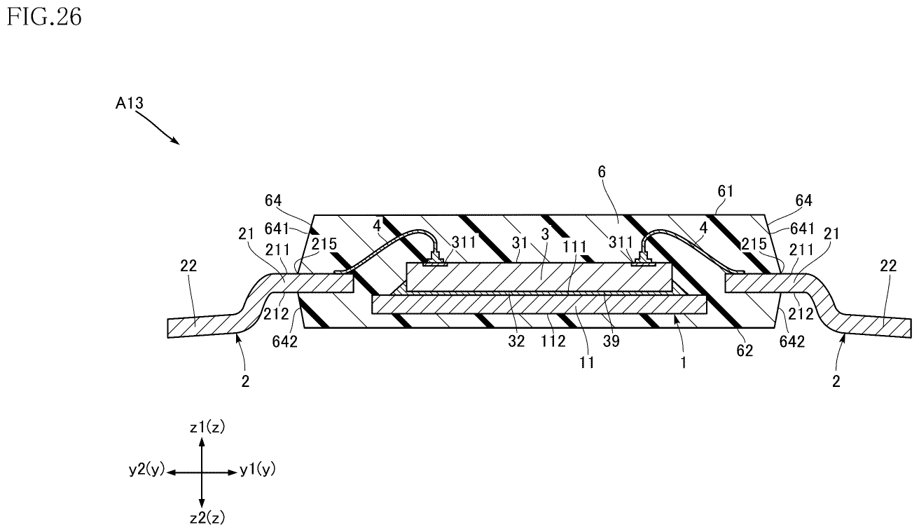

FIGS. 24 to 26 show a semiconductor device according to a third variation of the first embodiment. FIG. 24 is a plan view showing a semiconductor device A13 of the present variation, with the sealing resin 6 shown transparent. FIG. 25 is a cross-sectional view taken along line XXV-XXV in FIG. 24. FIG. 26 is a cross-sectional view taken along line XXVI-XXVI in FIG. 24. In FIG. 24, the sealing resin 6 is indicated by an imaginary line (two-dot chain line).

The semiconductor device A13 of the present variation is different from the semiconductor device A1 of the above embodiment mainly in the configurations of the second portions 12. In the present variation, each of the second portions 12 has a bent portion 125 and an end portion 126. The end portion 126 has a first end surface 123. The surface of the end portion 126 facing the z2 side in the thickness direction z is exposed from the resin reverse surface 62. The bent portion 125 is located between the end portion 126 and the first portion 11, and is inclined toward the z1 side in the thickness direction z as it extends to the first portion 11. The bent portion 125 and the end portion 126 having such configurations may be formed, for example, by bending the second portion 12 (the first lead 1). The first reverse surface 112 of the first portion 11 is offset to the z1 side in the thickness direction z relative to the resin reverse surface 62, and is covered with the sealing resin 6.

In the semiconductor device A13 of the present variation, the first lead 1 has the first end surfaces 123 that are located on the respective sides in the first direction x and exposed from the respective first resin side surfaces 63. Each of the first end surfaces 123 has a first edge 124 located on the z1 side in the thickness direction z. The second leads 2 protrude outward from the two second resin side surfaces 64 in the second direction y. Each of the second leads 2 has a second edge 215 located on the z1 side in the thickness direction z, in an area where the second lead 2 intersects a second resin side surface 64. The first edges 124 of the first lead 1 are located on the z2 side in the thickness direction z relative to the second edges 215 in the thickness direction z. With this configuration, the first lead 1 on which the semiconductor element 3 is mounted has no bent portion deformed in the thickness direction z by a depression process. This makes it possible to eliminate disadvantages that may arise when a bent portion is formed in a lead by a depression process, and to increase the size of the portion (the first portion 11) on which the semiconductor element 3 is mounted. In addition, the semiconductor device A13 has the same advantages as the semiconductor device A1 in the above embodiment within the range of the same configuration as that of the semiconductor device A1.

The semiconductor device according to the present disclosure is not limited to the embodiments described above. Various design changes can be made to the specific configurations of the elements in the semiconductor device according to the present disclosure.

According to the above embodiment, the package type of the semiconductor device is an SOP, and the parts of the second leads 2 that are exposed from the sealing resin 6 are each bent into a gull-wing shape. However, the present disclosure is not limited to this. The semiconductor device of the present disclosure may be provided in a dual in-line package (DIP) in which the second leads 2 exposed from the sealing resin 6 are bent and extend to the z2 side in the thickness direction z, or in a small outline J-leaded package (SOJ) in which the second leads 2 exposed from the sealing resin 6 are bent into a J-shape.

The present disclosure includes the embodiments described in the following clauses.

### Clause 1.

A semiconductor device comprising:
a semiconductor element;
a first lead on which the semiconductor element is mounted;
a plurality of second leads spaced apart from the first lead; and
a sealing resin covering the semiconductor element, the first lead, and the plurality of second leads,
wherein the semiconductor element is disposed on a first side in a thickness direction of the first lead,
the sealing resin includes a resin obverse surface facing the first side in the thickness direction, a resin reverse surface facing a second side in the thickness direction, two first resin side surfaces located between the resin obverse surface and the resin reverse surface and spaced apart from each other in a first direction perpendicular to the thickness direction, and two second resin side surfaces located between the resin obverse surface and the resin reverse surface and spaced apart from each other in a second direction perpendicular to the thickness direction and the first direction,
the first lead includes a first end surface exposed from one of the two first resin side surfaces,
the plurality of second leads include at least one second lead protruding from one of the two second resin side surfaces in the second direction,
the first end surface includes a first edge located on the first side in the thickness direction,
the at least one second lead includes a second edge located on the first side in the thickness direction, in an area where the at least one second lead intersects the one of the second resin side surfaces, and
the first edge is located on the second side in the thickness direction relative to the second edge.

### Clause 2.

The semiconductor device according to clause 1, wherein the first lead includes a first portion,
the first portion includes a first obverse surface facing the first side in the thickness direction, and a first reverse surface facing the second side in the thickness direction, and
the semiconductor element is supported by the first obverse surface.

### Clause 3.

The semiconductor device according to clause 2, wherein the first reverse surface is exposed from the resin reverse surface.

### Clause 4.

The semiconductor device according to clause 2 or 3, wherein the first lead includes a second portion connected to the first portion, and
the second portion includes the first end surface.

### Clause 5.

The semiconductor device according to clause 4, wherein the second portion includes a second obverse surface facing the first side in the thickness direction, and a second reverse surface facing the second side in the thickness direction, and
the second obverse surface is located on a same position as the first obverse surface in the thickness direction.

### Clause 6.

The semiconductor device according to clause 5, wherein the second reverse surface is exposed from the resin reverse surface.

### Clause 7.

The semiconductor device according to clause 6, wherein the second reverse surface is located on the same position as the first reverse surface in the thickness direction.

### Clause 8.

The semiconductor device according to clause 5, wherein the second reverse surface is covered with the sealing resin.

### Clause 9.

The semiconductor device according to clause 8, wherein the second reverse surface is located on the first side in the thickness direction relative to the first reverse surface.

### Clause 10.

The semiconductor device according to any one of clauses 2 to 9, wherein the first portion includes a periphery as viewed in the thickness direction, and the periphery includes a reverse-surface recess that is recessed from the first reverse surface to the first side in the thickness direction.

### Clause 11.

The semiconductor device according to any one of clauses 2 to 10, wherein the at least one second lead includes a lead portion that is partially covered with the sealing resin and extends in the second direction, and
the lead portion includes the second edge.

### Clause 12.

The semiconductor device according to clause 11, wherein the lead portion includes a third obverse surface facing the first side in the thickness direction, and a third reverse surface facing the second side in the thickness direction, and
the third obverse surface is located on the first side in the thickness direction relative to the first obverse surface.

### Clause 13.

The semiconductor device according to clause 12, further comprising a wire,
the semiconductor element includes an element obverse surface facing the first side in the thickness direction, and an element reverse surface facing the second side in the thickness direction and opposes the first obverse surface, and
the wire is bonded to the element obverse surface and the third obverse surface.

### Clause 14.

The semiconductor device according to any one of clauses 11 to 13, wherein the at least one second lead includes a terminal portion connected to the lead portion, and
the terminal portion is located on the second side in the thickness direction relative to the lead portion.

### Clause 15.

The semiconductor device according to any one of clauses 1 to 14, wherein the one of the second resin side surfaces includes a first region connected to the resin obverse surface, a second region connected to the resin reverse surface, and a third region located between the first region and the second region in the thickness direction, and
the at least one second lead protrudes from the third region.

### Clause 16.

The semiconductor device according to clause 15, wherein the one of the two first resin side surfaces includes a fourth region connected to the resin obverse surface, and a fifth region connected to the fourth region on the second side in the thickness direction,
the fifth region is located on the second side in the thickness direction relative to the third region, and
the first end surface is exposed from the fifth region.

### Clause 17.

The semiconductor device according to clause 15, wherein each of the two first resin side surfaces is a flat surface perpendicular to the first direction.

### REFERENCE NUMERALS

A1, A11, A12, A13: Semiconductor device
1: First lead
10: Lead
11: First portion
111: First obverse surface
112: First reverse surface
113: Reverse-surface recess
12, 120: Second portion
121: Second obverse surface
122: Second reverse surface
123: First end surface
124: First edge
125: Bent portion
126: End portion
130: Bent portion
2: Second lead
20: Lead
21: Lead portion
210: Tie bar
211: Third obverse surface
212: Third reverse surface
213: Pad portion
214: Strip portion
215: Second edge
22: Terminal portion
3: Semiconductor element
31: Element obverse surface
311: Electrode pad
32: Element reverse surface
39: Bonding material
4: Wire
6: Sealing resin
61: Resin obverse surface
62: Resin reverse surface
63: First resin side surface
631: Fourth region
632: Fifth region
64: Second resin side surface
641: First region
642: Second region
643: Third region
8: Mold
81: Lower mold
82: Upper mold
810, 820: Cavity
811, 812, 821, 822: Mating surface
F: Frame
LF: Lead frame

1. A semiconductor device comprising:
a semiconductor element;
a first lead on which the semiconductor element is mounted;
a plurality of second leads spaced apart from the first lead; and
a sealing resin covering the semiconductor element, the first lead, and the plurality of second leads,
wherein the semiconductor element is disposed on a first side in a thickness direction of the first lead,
the sealing resin includes a resin obverse surface facing the first side in the thickness direction, a resin reverse surface facing a second side in the thickness direction, two first resin side surfaces located between the resin obverse surface and the resin reverse surface and spaced apart from each other in a first direction perpendicular to the thickness direction, and two second resin side surfaces located between the resin obverse surface and the resin reverse surface and spaced apart from each other in a second direction perpendicular to the thickness direction and the first direction,
the first lead includes a first end surface exposed from one of the two first resin side surfaces,
the plurality of second leads include at least one second lead protruding from one of the two second resin side surfaces in the second direction,
the first end surface includes a first edge located on the first side in the thickness direction,
the at least one second lead includes a second edge located on the first side in the thickness direction, in an area where the at least one second lead intersects the one of the second resin side surfaces, and
the first edge is located on the second side in the thickness direction relative to the second edge.

2. The semiconductor device according to claim 1, wherein the first lead includes a first portion,
the first portion includes a first obverse surface facing the first side in the thickness direction, and a first reverse surface facing the second side in the thickness direction, and
the semiconductor element is supported by the first obverse surface.

3. The semiconductor device according to claim 2, wherein the first reverse surface is exposed from the resin reverse surface.

4. The semiconductor device according to claim 2, wherein the first lead includes a second portion connected to the first portion, and
the second portion includes the first end surface.

5. The semiconductor device according to claim 4, wherein the second portion includes a second obverse surface facing the first side in the thickness direction, and a second reverse surface facing the second side in the thickness direction, and
the second obverse surface is located on a same position as the first obverse surface in the thickness direction.

6. The semiconductor device according to claim 5, wherein the second reverse surface is exposed from the resin reverse surface.

7. The semiconductor device according to claim 6, wherein the second reverse surface is located on the same position as the first reverse surface in the thickness direction.

8. The semiconductor device according to claim 5, wherein the second reverse surface is covered with the sealing resin.

9. The semiconductor device according to claim 8, wherein the second reverse surface is located on the first side in the thickness direction relative to the first reverse surface.

10. The semiconductor device according to claim 2, wherein the first portion includes a periphery as viewed in the thickness direction, and the periphery includes a reverse-surface recess that is recessed from the first reverse surface to the first side in the thickness direction.

11. The semiconductor device according to claim 2, wherein the at least one second lead includes a lead portion that is partially covered with the sealing resin and extends in the second direction, and
the lead portion includes the second edge.

12. The semiconductor device according to claim 11, wherein the lead portion includes a third obverse surface facing the first side in the thickness direction, and a third reverse surface facing the second side in the thickness direction, and
the third obverse surface is located on the first side in the thickness direction relative to the first obverse surface.

13. The semiconductor device according to claim 12, further comprising a wire,
the semiconductor element includes an element obverse surface facing the first side in the thickness direction, and an element reverse surface facing the second side in the thickness direction and opposes the first obverse surface, and
the wire is bonded to the element obverse surface and the third obverse surface.

14. The semiconductor device according to claim 11, wherein the at least one second lead further includes a terminal portion,
the terminal portion is connected to one of two ends of the lead portion in the second direction, the end being located farther from the first portion than the other end, and
the terminal portion is located on the second side in the thickness direction relative to the lead portion.

15. The semiconductor device according to claim 1, wherein the one of the second resin side surfaces includes a first region connected to the resin obverse surface, a second region connected to the resin reverse surface, and a third region located between the first region and the second region in the thickness direction, and
the at least one second lead protrudes from the third region.

16. The semiconductor device according to claim 15, wherein the one of the two first resin side surfaces includes a fourth region connected to the resin obverse surface, and a fifth region connected to the fourth region on the second side in the thickness direction,
the fifth region is located on the second side in the thickness direction relative to the third region, and
the first end surface is exposed from the fifth region.

17. The semiconductor device according to claim 15, wherein each of the two first resin side surfaces is a flat surface perpendicular to the first direction.
